(19) United States
(12) Patent Application Publication
(10) Pub. No.: US 2004/0256692 A1
(43) Pub. Date: Dec. 23, 2004

(54) Composite analog power transistor and method for making the same

(76) Inventors: Keith Edmund Kunz, Juan-les Pins (FR); Gerardo Alberto Olmos, El Paso, TX (US); Dan Michael Mosher, Plano, TX (US); Greg Charles Baldwin, Plano, TX (US)

Correspondence Address: TEXAS INSTRUMENTS INCORPORATED, P O BOX 655474, M/S 3999, DALLAS, TX, 75265

(21) Appl. No.: 10/863,679

(22) Filed: Jun. 8, 2004

Related U.S. Application Data
(60) Provisional application No. 60/479,686, filed on Jun. 19, 2003.

(51) Int. Cl. H03D 1/00

(52) U.S. Cl. 257/500

(57) ABSTRACT

A composite transistor (TC) is provided, comprising an extended drain MOS transistor (T1) and a symmetrical MOS transistor (T2) sharing a common source/drain (114b). A method is presented for fabricating an integrated circuit, comprising forming an extended drain (114a, 120) of a first conductivity type in a semiconductor body (104), forming a source (114c) of the first conductivity type in the semiconductor body (104), forming a first channel (128a) of a second conductivity type along at least a portion of a side of the extended drain (114a, 120) in the semiconductor body (104), forming a second channel (128b) of the second conductivity type along at least a portion of a side of the source (114c), and forming a shared source/drain (114b) of the first conductivity type extending between the first and second channels (128a, 128b).

### FIELD OF INVENTION

The present invention relates generally to semiconductor devices and more particularly to improved analog power transistors and fabrication methods for making the same.

### BACKGROUND OF THE INVENTION

Many integrated circuits require power transistor devices that switch power at relatively high voltages. Dedicated analog integrated circuits are typically fabricated using processes optimized for power transistor performance in power management circuits, low drop-out voltage regulators, analog base band amplifiers, and the like. However, many modern products include both high voltage analog power components and lower voltage digital circuitry, wherein newer products are continually being introduced having ever higher amounts of high-speed memory and other digital circuitry. For example, wireless communications products and other portable consumer products often include high-density digital logic and memory circuits, as well as power management circuitry coupled with battery-based power sources, wherein analog power management and digital logic functionality are implemented in a single integrated circuit. In the case of battery-power consumer products, energy efficiency is an important design parameter, wherein newer products are designed for lower power consumption and operation at lower supply voltages. In addition, ever-higher device densities are needed to provide additional product functionality and data storage capabilities, while products are continually being designed for smaller and smaller packages.

Power switching circuitry as well as digital logic and memory circuits within many semiconductor products typically include N or P channel metal-oxide-semiconductor (MOS) transistors. Digital logic and memory circuits often include MOS transistors that are optimized for high-speed switching operation, as well as high device density (small transistor feature sizes and spacing). On the other hand, it is desirable to optimize higher voltage power switching circuits and MOS transistors thereof according to energy efficiency performance. Hybrid semiconductor integrated circuits having both low voltage and high voltage transistors are increasingly being fabricated using deep-submicron fabrication processes that are optimized for the performance of the high-speed, high-density logic circuitry, wherein a relatively large portion of the circuit area is occupied by power circuitry.

FIG. 1A schematically illustrates an integrated circuit (IC) 2 having a power management circuit coupled with a battery voltage V_{BAT} for providing a supply current I_{OUT}. The IC 2 includes an amplifier A and a PMOS type power transistor T having a source S coupled to the battery voltage V_{BAT} and a drain coupled to a resistive voltage divider R1, R2, wherein R2 is grounded, a feedback node between R1 and R2 is provided to a non-inverting input of the amplifier A, and an inverting input of the amplifier A is coupled to a reference voltage V_{REF}. In operation, the amplifier A controls a gate terminal G of the transistor T such that the voltage at the intermediate node of the resistive divider is equal to the reference voltage V_{REF}, whereby a regulated drain voltage is maintained and the output current I_{OUT} is provided for use by other circuits (not shown) in the IC 2.

FIG. 1B further illustrates the PMOS transistor T of the IC 2, including an n-well 6 and field oxide (FOX) isolation structures 8 formed in the substrate 4, with a gate oxide 10 and a conductive gate electrode 12 formed above a channel region of the substrate 4 (e.g., over a portion of the n-well 6). P+ doped source/drains 14 are formed in the n-well on either side of the channel region, with sidewall spacers 16 formed along vertical sidewalls of the gate 12, and conductive silicide 18 formed over the source/drains 14 and the gate 12. In operation, application of a gate voltage more than a threshold voltage Vt below V_{BAT} creates a field in the channel region of the n-well 6, causing the transistor T to turn on whereby current is allowed to conduct between the source 14 and the drain 14. In applications such as that of FIG. 1A where power switching circuits are connected to a battery, it is desirable to minimize the leakage current through the transistor T when the device is in “standby” or “off” operational modes.

Referring also to FIG. 1C, continuing trends in semiconductor product manufacturing include reducing electrical device feature sizes (scaling), as well as improving device performance in terms of drive current, device switching speed, and power consumption. For the same applied voltage, the drive current (e.g., “on-state” current) may be increased by reducing the channel distance L (e.g., gate length) between the source and the drain regions 14 under the gate 12, however, short channel effects such as reduced threshold voltage (Vt) and subthreshold leakage limit the amount of scaling that can be achieved without also reducing the applied voltage.

With respect to high voltage applications, drain-to-source voltages have a greater impact on channel performance in short channel devices, wherein the barrier for electron injection from the source to the drain may be decreased, a situation sometimes referred to as drain induced barrier lowering (DIBL). DIBL can lead to lowered device threshold voltage (Vt) with increased leakage current when the transistor T sees a non-zero drain-to-source voltage (Vds). FIG. 1C illustrates an energy barrier diagram 20 for the conventional high voltage PMOS transistor T, including a first curve 21 showing the energy barrier for drain-to-source conduction for a zero gate-to-source voltage (Vgs) and zero Vds. Application of a non-zero Vds results in a lowered energy barrier, as illustrated by the dashed line curve 22 in FIG. 1C, wherein the presence of a voltage at the source S worsens the leakage current of the transistor T.

The illustrated transistor T of FIG. 1B is a generally symmetrical high voltage PMOS transistor in which the source/drains 14 are roughly the same size, wherein integration of high voltage transistors T into sub-micron logic device fabrication processes typically involved addition of extra masks and processing steps to provide a relatively thick gate oxide 10 for the power transistor T, as well as a thinner gate oxide for lower voltage logic transistors (not shown). Asymmetrical power transistor designs are sometimes used, in which one of the source/drains (e.g., typically the drain) is longer and/or deeper and lighter than the other, sometimes referred to as drain-extended MOS (DEMOS) transistor devices, for power switching applications. DEMOS devices generally provide short-channel operation with high current handling capabilities, relatively low drain-to-source on-state resistance (Rdson), and the ability to withstand high blocking voltages without suffering voltage breakdown failure. DEMOS device fabrication is also relatively easy to integrate into sub-micron CMOS fabrication process flows, facilitating use in products where logic, low power analog, or other circuitry is also to be fabricated in a single IC. Although DEMOS transistors advantageously facilitate integration of high and low voltage transistors in a single circuit, there remains a need for analog power devices with reduced areas and reduced leakage for use in modern hybrid semiconductor products.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention relates to the combination of an extended drain MOS transistor (DEMOS) with a symmetrical MOS transistor (e.g., such as a low voltage core logic transistor, high voltage input/output transistor, or other non-DEMOS transistor) to form a composite transistor having a shared or a common source/drain, where the DEMOS and the symmetrical transistors can be formed on either side of the common source/drain or the common source/drain can be otherwise electrically coupled so as to be shared by to the two transistors. The inventors have appreciated that such a composite transistor structure can facilitate reduction in off-state leakage, without adverse impact on power device area usage, and without adding complexity or extra masks to sub-micron CMOS fabrication processes. Thus, the invention may find particular utility in switching battery supplied electrical current in portable consumer electronics and other products, wherein battery life may be extended by reducing “off-state” or “standby mode” power consumption.

In the examples illustrated and described below, the composite transistor requires no extra masking, wherein the drain-extended transistor and the symmetrical transistor have substantially equal gate dielectric thicknesses, with the drain-extended transistor having a larger channel length than the symmetrical transistor. In this configuration, the drain-extended transistor effectively operates to provide an extended composite drain to absorb the majority of an applied overall drain-to-source voltage Vds, whereby the symmetrical transistor portion itself is only exposed to a much smaller voltage between the source and the shared source/drain. In this manner, threshold voltage lowering and the associated leakage currents are largely avoided for the symmetrical transistor, whereby the overall composite transistor leakage current is reduced compared with conventional symmetrical high voltage transistors or conventional drain-extended (stand-alone DEMOS) devices.

In one implementation, a PMOS composite transistor is provided, wherein the DEMOS transistor has a larger channel length than the symmetrical transistor. Pocket implants may be provided in one or both of the two composite device channels to increase the effective threshold voltage Vt for leakage improvement, without adverse effects of drain induced barrier lowering (DIBL), whereby performance metrics such as the ratio between on-state drive current and leakage current (e.g., I_{ON}/I_{OFF}) may be increased without increasing the area usage for power transistors in an IC. The inventors have found that composite transistors in accordance with the present invention may be constructed having the same or smaller channel lengths and smaller total device area, with far lower leakage currents in comparison with conventional symmetrical or asymmetrical transistors, while still achieving equivalent drive current ratings.

One aspect of the invention provides an analog power integrated circuit, comprising first and second MOS transistors sharing a common source/drain. The first transistor is a drain-extended device (DEMOS) comprising an extended drain of a first conductivity type, a first channel region of a second conductivity type, and a first gate formed at least partially over the first channel. The second transistor can be a symmetrical transistor, such as a core logic transistor, an I/O transistor, or other symmetrical device, comprising a source of the first conductivity type formed in the semiconductor body, a second channel region of the second conductivity type formed in the semiconductor body, and a second gate formed at least partially over the second channel region. A shared source/drain of the first conductivity type is provided between the first and second channel regions in the semiconductor body, wherein the first channel region extends between the extended drain and the shared source/drain, and wherein the second channel region extends laterally between the source and the shared source/drain.

Another aspect of the invention provides a composite transistor, comprising an extended drain MOS transistor, and a symmetrical MOS transistor, wherein the extended drain MOS transistor and the symmetrical MOS transistor share a common source/drain. Yet another aspect of the invention provides a method of fabricating an integrated circuit, comprising forming an extended drain of a first conductivity type in a semiconductor body, forming a source of the first conductivity type in the semiconductor body, forming a first channel of a second conductivity type alongside the extended drain in the semiconductor body, forming a second channel of the second conductivity type alongside the source, forming a shared source/drain of the first conductivity type extending between the first and second channels, and forming first and second gates over at least portions of the first and second channels, respectively.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1A is a schematic diagram illustrating a portion of an integrated circuit having a power management circuit with a conventional PMOS transistor;

FIG. 1B is a side elevation view in section illustrating the conventional PMOS transistor of FIG. 1A;

FIG. 1C is an energy barrier diagram illustrating drain induced barrier lowering (DIBL) in the conventional transistor of FIGS. 1A and 1B;

FIG. 2A is a schematic diagram illustrating a portion of an integrated circuit having a power management circuit with an exemplary composite PMOS transistor in accordance with one or more aspects of the invention;

FIG. 2B is a side elevation view in section illustrating further details of the exemplary composite transistor of FIG. 2A;

FIG. 2C is an energy barrier diagram illustrating off-state energy barriers at two different Vds levels for the composite transistor of FIGS. 2A and 2B;

FIG. 3 is a flow diagram illustrating an exemplary method of fabricating an integrated circuit in accordance with the invention; and

FIGS. 4A-4I are partial side elevation views in section illustrating the exemplary composite transistor integrated circuit of FIG. 2B at various stages of fabrication in accordance with the invention.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale. The invention provides transistor structures and methods by which off-state leakage current (I_{OFF}) can be reduced and drive current (I_{ON}) can be improved, without increasing the overall area occupied by power transistors, and without adding extra processing steps or cost in manufacturing hybrid integrated circuits using sub-micron fabrication process flows. Various aspects of the invention are hereinafter illustrated and described in the context of an exemplary composite PMOS transistor forming part of a current source circuit fabricated in a silicon substrate. However, other implementations of the invention are possible, including NMOS embodiments and integrated circuits formed in other types of semiconductor bodies (e.g., wafers with epitaxial silicon formed over a substrate, SOI wafers, etc.), wherein the invention is not limited to the illustrated examples.

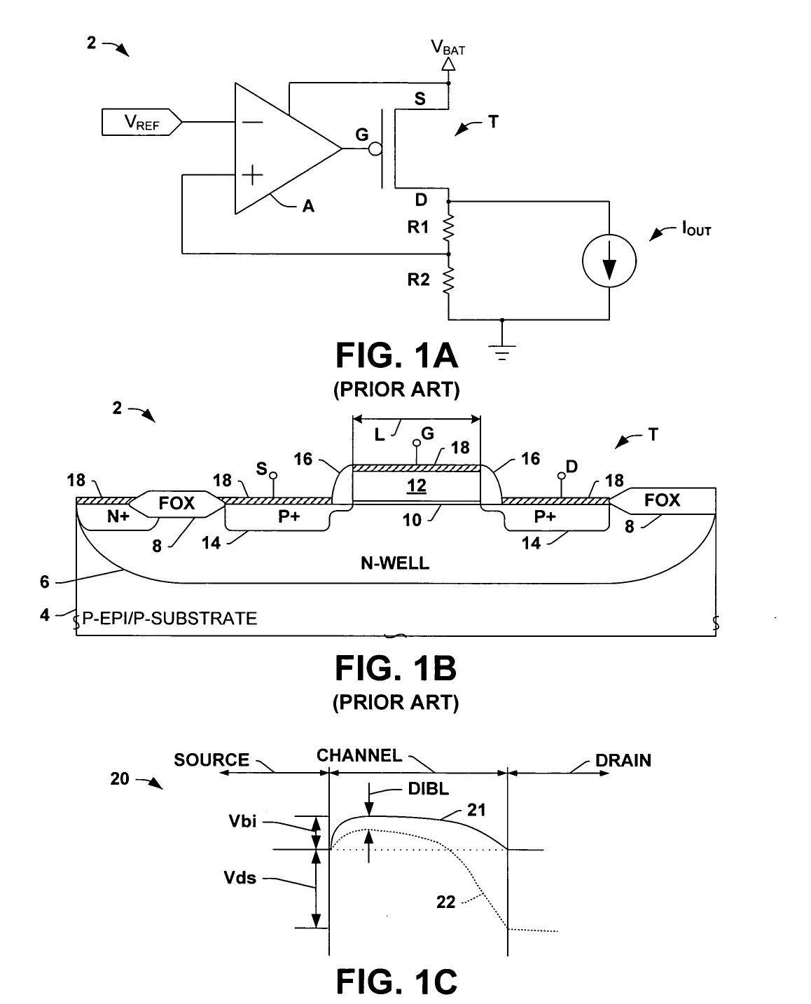

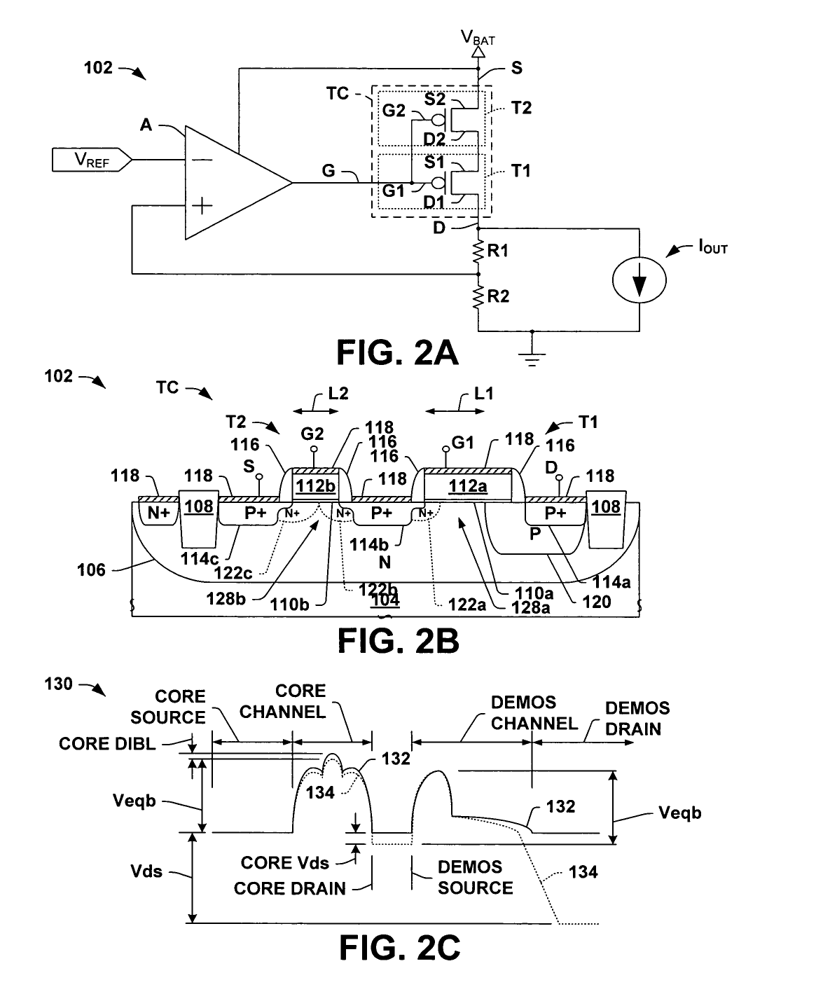

FIGS. 2A and 2B illustrate an exemplary integrated circuit 102 formed in a p-doped silicon substrate semiconductor body 104, including a composite PMOS transistor TC in accordance with the invention. In FIG. 2A, the composite transistor TC is connected in a power management circuit otherwise similar to that illustrated in FIG. 1A above for providing a current I_{OUT} from a battery supply voltage V_{BAT} using an amplifier A and a resistive voltage divider R1, R2. The composite transistor TC has a source terminal S, a drain terminal D, and a gate G, where the source S is coupled with the battery voltage V_{BAT}, the drain D is coupled with the resistor R1 and the amplifier output controls the gate G.

The composite transistor TC comprises first and second transistors T1 and T2, respectively, sharing a common source/drain S1, D2. As further illustrated in FIG. 2B, the first transistor T1 is a drain-extended device (DEMOS), comprising an extended p-type drain 114a, 120 (D1 in FIG. 2A) that provides the composite transistor drain D, a common (e.g., shared) p-type source 114b (S1 in FIG. 2A), and a gate 112a (G1 in FIG. 2A) coupled with the composite transistor gate G. In the illustrated device 102, the drain D comprises a P+ drain implant region 114a formed within a compensated p-well 120, where the p-well 120 provides a lateral drain extension region between the P+ drain 114a and a first channel region 128a of the semiconductor body 104. The lateral extent of the drain extension compensated p-well 120 sets a first channel length L1 of the first transistor T1 between the p-well 120 and the P+ shared source/drain 114b under a portion of the first gate 112a. Other forms and types of extended drains may alternatively be provided in composite transistors within the scope of the invention, for example, shallow REduced SURface Field (RESURF) implanted regions extending from the drain 114a to the first channel 128a, wherein all such variant implementations are contemplated as falling within the scope of the present invention.

The second transistor T2 shares the p-type common source/drain 114b (D2 in FIG. 2A), and also comprises a p-type source 114c (S2 in FIG. 2A) and a second gate 112b (G2 in FIG. 2A) that may be coupled with the first gate G1 to form the composite transistor gate G as illustrated in the exemplary circuit of FIG. 2A. Other implementations are possible, in which the gates G1 and G2 are tied to separate electrical signals, wherein all such alternative implementations are contemplated as falling within the scope of the invention and the appended claims. In the illustrated example, the second transistor T2 is a generally symmetrical transistor, which may be formed using the same materials, and processing steps used to form other low voltage logic transistors (e.g., core logic transistors, not shown) or symmetrical high voltage I/O transistors (not shown) in the IC 102, whereby no additional processing steps or complexity need be added to existing sub-micron fabrication processing in order to create the composite transistor TC of the invention. The lateral extent of the P+ source 114c and the shared source/drain 114b define a second channel 128b having a channel length L2 under the second gate 112b in the second transistor T2. In the exemplary IC 102, the first channel length L1 of the extended-drain transistor T1 is larger than the second channel length L2 of the symmetrical transistor T2, although this is not a strict requirement of the invention. The source 114c, the drain 114a, 120, and the shared source/drain 114b may be formed to any appropriate dimensions and dopant concentrations by any suitable means, wherein dopants of a first conductivity type (e.g., p-type in the illustrated PMOS implementation) are provided to the regions 114, 120 of the semiconductor body 104. In this regard, the widths of the first and second channels 128a and 128b are generally the same in the illustrated implementation, although the channel widths may be different, wherein all such variant implementations are contemplated as falling within the scope of the present invention and the appended claims.

As shown in FIG. 2B, the exemplary IC 102 further comprises an n-well 106 formed in the semiconductor body 104, as well as isolation structures 108 positioned laterally outward of the composite source S and the drain D. The n-well 106 provides the n-type channel regions 128 of the semiconductor body 104 beneath portions of the gates G1 and G2, wherein the first n-type channel region 128a extends between the extended drain 114a, 120 and the shared source/drain 114b, and the second n-type channel region 128b extends laterally between the composite device source 114c and the shared source/drain 114b. The channels 128 may alternatively be formed using different n-wells or by any other means of providing dopants of a second conductivity type (e.g., n-type in the illustrated example) in channel regions extending between the first conductivity type source/drains 114. In the exemplary IC 102, three N+ pocket implant regions 122 are provided to the channels 128, with a first pocket implant region 122a being located at the shared source/drain end of the first channel 128a. Second and third pocket implant regions 122b and 122c being located at the shared source/drain and source ends of the second channel 128b, respectively, where the pocket implants 122b and 122c may, but need not, overlap.

In applications in which the gates G1 and G2 are to be commonly driven, the gates G1 and G2 may be coupled with one another by any suitable means, for example, in an interconnect layer (metalization layer) formed above the transistors T1 and T2 (not shown). The gates G1 and G2 individually comprise a gate dielectric 110 and a conductive gate electrode 112, which can be any suitable materials and may be multilayer structures of any suitable dimensions within the scope of the invention. In the illustrated IC 102, the first and second gate dielectrics 110a and 110b, respectively, are both of the same vertical thickness, although different gate dielectric materials and/or thicknesses may be used. The first gate G1 comprises a first gate dielectric 110a (e.g., SiO₂) formed at least partially over the first channel 128a and a conductive first gate electrode 112a (e.g., doped polysilicon) formed at least partially over the first gate dielectric 110a.

The exemplary second gate G2 comprises a second SiO₂ gate dielectric 110b formed at least partially over the second channel 128b, and a conductive second gate electrode 112b (polysilicon) formed at least partially over the second gate dielectric 110b. Sidewall spacers 116 are formed along the lateral sides of the gates 112, and conductive metal silicide material 118 is formed at the upper surfaces of the gates G1, G2, the source 114c, and the drain 114a, and may also be formed over the shared source drain 114b, although no external connection to the shared source drain 114b is required. Although the exemplary composite transistor TC is a PMOS type, the various aspects of the invention are also applicable to NMOS composite transistors, in which n-doped regions may generally be replaced with p-doped regions and vice-versa (e.g., n-type source, extended drain, and shared source/drain, with p-type channel regions). Moreover, composite transistors of the invention may be fabricated using any suitable processing techniques.

The exemplary composite transistor device TC thus combines an extended drain MOS transistor T1 with a symmetrical MOS transistor T2 to create the composite transistor TC, in which the transistors T1 and T2 share the common source/drain 114b. The composite transistor aspects of the invention can be employed to reduce off-state leakage currents, wherein the drain-extended transistor T1 operates to shield the symmetrical transistor T2 from most of the composite drain-to-source voltage Vds (e.g., the voltage between the source 114c and the extended drain 114a), whereby the symmetrical transistor T2 remains largely unaffected by drain-induced barrier lowering and consequently inhibits leakage currents from flowing through the composite transistor TC.

FIG. 2C illustrates an energy barrier diagram 130 for the exemplary composite transistor TC, wherein a solid-line curve 132 shows the off-state (e.g., zero Vgs) energy barrier with no drain-to-source voltage Vds, and a dashed line curve 134 illustrates the off-state barrier in the presence of a non-zero Vds. As illustrated in FIG. 2C, the effects of DIBL are largely avoided in the composite transistor TC where the interaction between the DEMOS and symmetrical transistors T1 and T2, respectively, provides an equilibrium barrier Veqb that is largely independent of Vds levels, thereby inhibiting off-state leakage. Thus, the invention provides controllability of leakage currents. In addition, the provision of the N+ pocket implant regions 122 set the level of the barrier, wherein the combination of the first and second transistors T1 and T2, together with the pocket implants 122 provides significant improvement compared with conventional high voltage symmetrical MOS power transistor designs and stand alone DEMOS devices.

As illustrated in FIG. 2C, the composite transistor TC creates a higher barrier diagram (e.g., wherein the voltage Vds of FIG. 2C is greater in the transistor TC than was the case in FIG. 1C above). Also, the barrier diagram 130 is much more independent of the biasing conditions, such that even as Vds is increased, the energy barrier diagram stays about the same, whereas the barrier curve 22 in FIG. 1C falls much farther below the curve 21 when Vds is non-zero. Thus, for example, in the application of FIG. 2A, the composite transistor TC can be successfully shut off or placed in standby mode (e.g., zero Vgs) even when the source S remains connected to the battery voltage V_{BAT}, without significant leakage through the transistor TC. In this regard, the improved DIBL control provides a composite transistor TC that retains it's effective threshold voltage (Vt) characteristics essentially irrespective of Vds levels.

In the composite transistor TC, most of the Vds voltage drops across the extended drain (e.g., in the compensated P-WELL region 120 in FIG. 2B). In FIG. 2C, this is indicated by the curve 134 at the right hand side of the diagram 130, wherein only a small fraction of the total Vds is seen by the symmetrical transistor T2 (e.g., “CORE Vds” in FIG. 2C). As a result, the overall transistor DIBL is essentially set by the symmetrical transistor T2 (e.g., “CORE DIBL” in FIG. 2C), which is effectively shielded from Vds by the DEMOS T1. As a further advantage of the interaction between the transistors T1 ands T2, the inventors have found that the energy barrier peak in the symmetrical transistor channel 128b in FIG. 2C is higher than in the conventional high voltage symmetrical transistor T of FIG. 1B, and is also higher than corresponding conventional DEPMOS transistors having similar drive current ratings.

As a result, I_{ON}/I_{OFF} ratio figures of merit are much higher and more controllable for the composite transistors of the invention, since the symmetrical transistor T2 is the primary determinant of the leakage current I_{OFF} Further, the inventors have found that the on-state drive current is better controlled than in similarly sized conventional devices, because the controllability of the symmetrical transistors T2 in sub-micron fabrication processes is generally better than that of high voltage devices. Moreover, since the DEMOS transistor T1 effectively clamps the voltage seen by the symmetrical transistor T2 (CORE Vds in FIG. 2C), the symmetrical transistor T2 and the channel length L2 thereof can be made smaller than other symmetrical transistors in a given device 102. In addition, any variation in the total composite transistor Vds is not seen by the symmetrical transistor T2, wherein the composite drive current is more controllable than in conventional devices. The inventors have also found that the channel lengths L1 and L2 of both transistors T1 and T2 can be reduced in comparison with conventional transistors, while still attaining an equivalent drive current, with the same or smaller total device area, with far lower leakage currents.

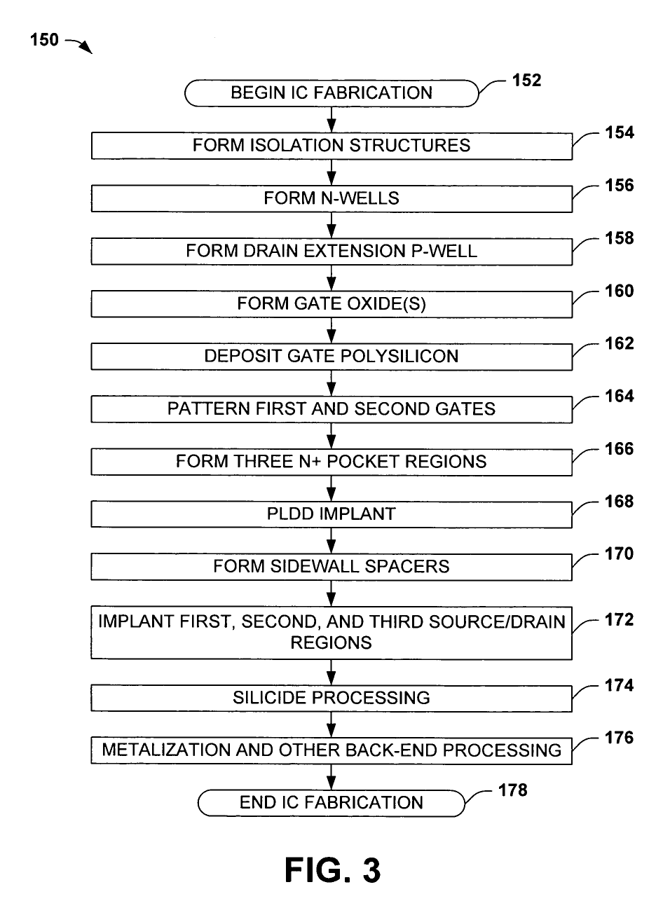

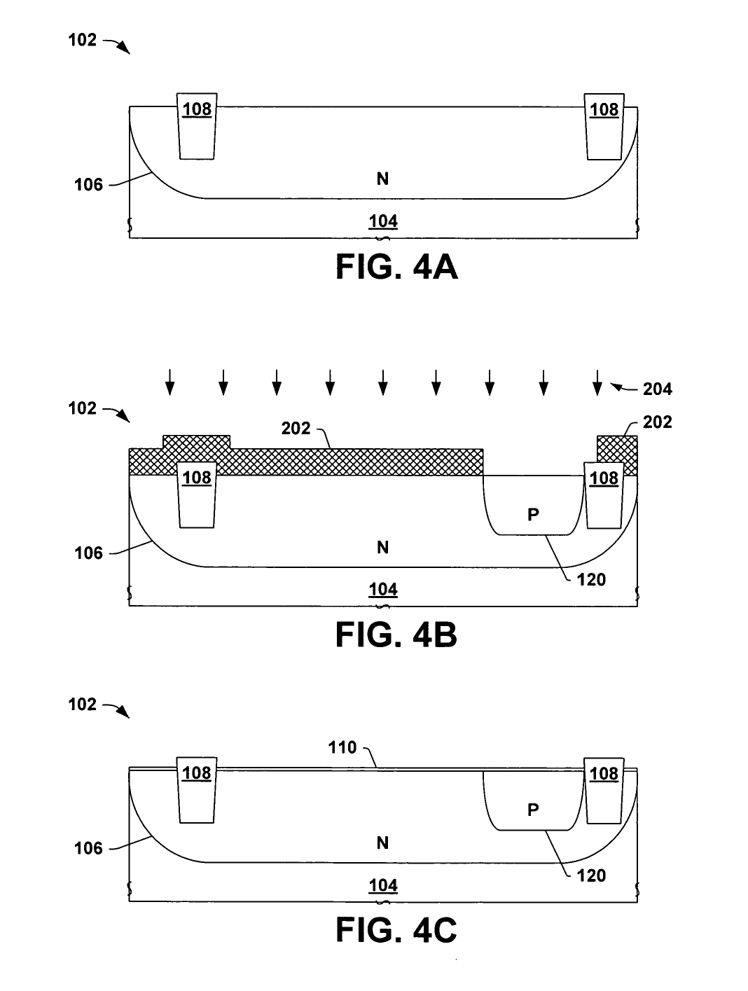

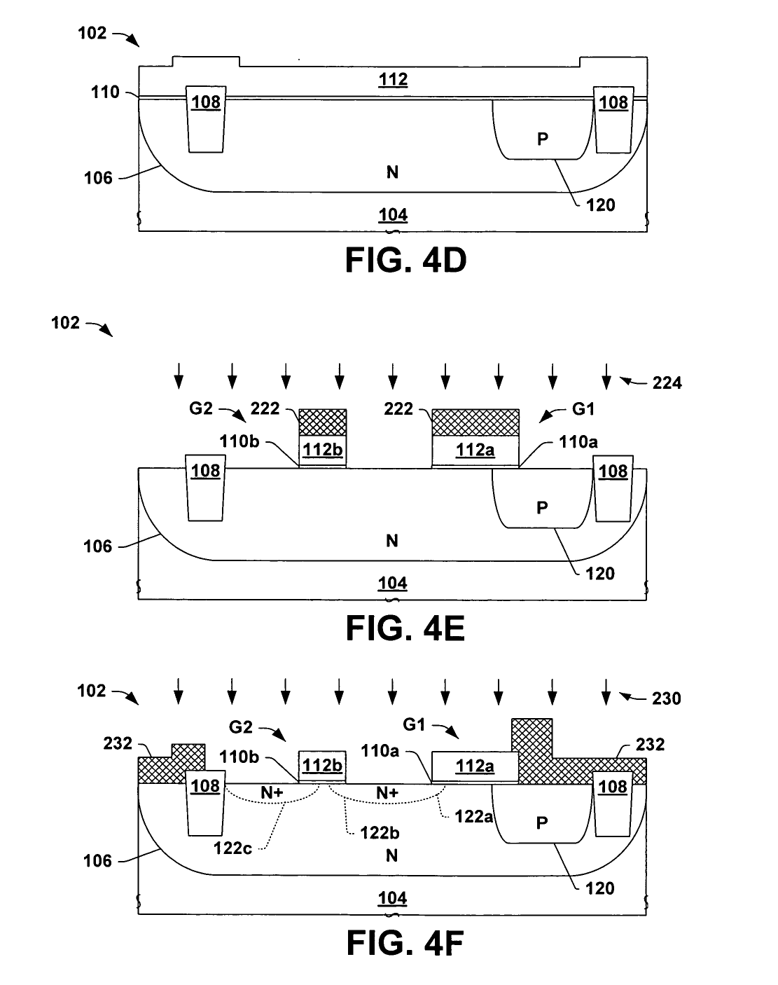

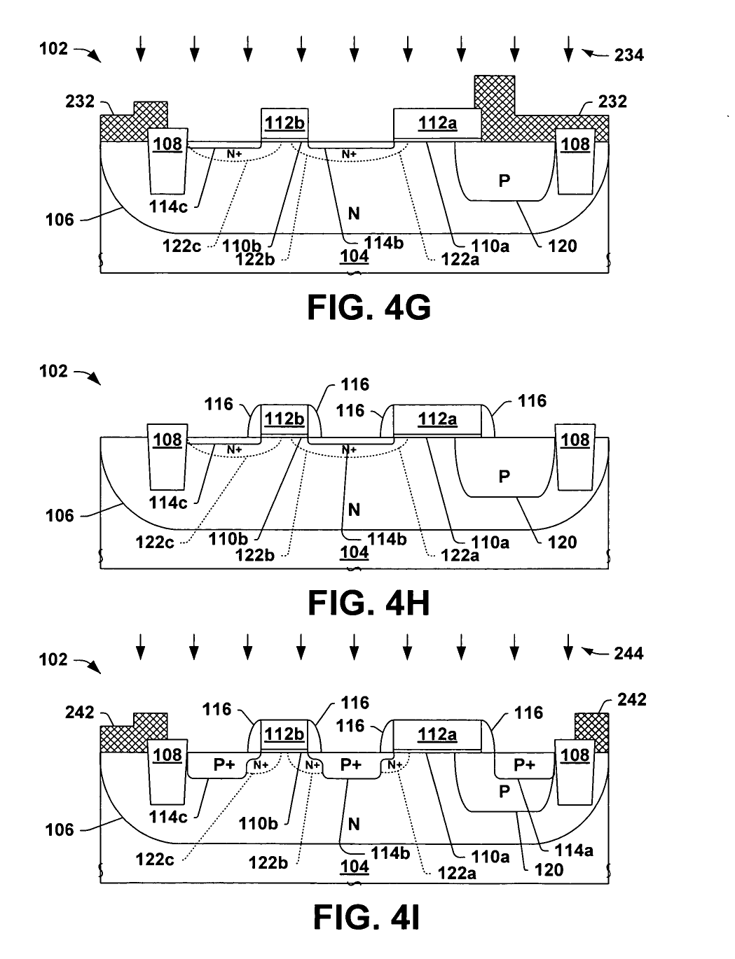

Referring now to FIGS. 3 and 4A-4I, further aspects of the invention relate to methods of fabricating integrated circuits, wherein FIG. 3 illustrates an exemplary method 150 in accordance with the invention, and FIGS. 4A-4I illustrate the exemplary composite transistor TC in the IC 102 of FIG. 2B at various stages of fabrication in accordance with the invention. In one aspect of the invention, the exemplary method 150 involves forming an extended drain of a first conductivity type, forming a source of the first conductivity type in the semiconductor body, forming a first channel of a second conductivity type alongside the extended drain in the semiconductor body, forming a second channel of the second conductivity type alongside the source, and forming a shared source/drain of the first conductivity type extending between the first and second channels. In another aspect of the invention, the method 150 provides for forming a first pocket implant region of the second conductivity type in a portion of the first channel along a portion of the shared source/drain, forming a second pocket implant region of the second conductivity type in a portion of the second channel along another portion of the shared source/drain, and forming a third pocket implant region of the second conductivity type in the another portion of the second channel along a portion of the source.

While the exemplary method 150 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the fabrication of ICs and composite transistors illustrated and described herein, as well as in association with other transistors and structures not illustrated, including but not limited to NMOS and/or PMOS composite transistors.

Beginning at 152 in FIG. 3, isolation processing is performed at 154 to form isolation structures in a semiconductor body, such as local oxidation of silicon (LOCOS) processing to create field oxide structures and/or shallow trench isolation (STI) processes. For example, the isolation structures 108 are formed in the semiconductor body 104 in FIG. 4A at 154 in the method 150. One or more n-wells are then formed in the semiconductor body at 156 (e.g., n-well 106 in FIG. 4A), through implantation and/or diffusion of one or more n-type dopants (e.g., P, As, Sb, etc.) with suitable annealing or other suitable processing steps.

At 158, a compensated p-well is formed in a prospective drain extension region of the semiconductor body through implantation and/or diffusion of p-type dopants therein (e.g., B, Ga, etc.). As illustrated in FIG. 4B, a mask 202 is formed over the device 102, exposing a prospective drain extension region, and an implantation process 204 is performed to provide p-type dopants to the drain extension p-well 120 within a portion of the previously formed n-well 106, wherein the compensated p-well 120 extends within the semiconductor body to a depth that is less than the depth of the n-well 106. Alternative drain extensions may be formed at 158, for example, such as one or more shallower n-type reduced surface (RESURF) implants extending between the subsequently formed drain 114a and the first channel 128a (FIG. 2B), wherein all such variant implementations are contemplated as falling within the scope of the present invention and the appended claims.

At 160, a gate dielectric is formed over the wafer, which may be any suitable dielectric material or materials, such as a single thermally grown SiO₂ or other suitable single or multi-layer oxide or other dielectric material of any suitable thickness. In the exemplary IC 102 of FIG. 4C, a thin gate oxide 110 is formed by annealing the IC 102 in an oxidizing ambient, where the resulting oxide 110 covers the surface of the semiconductor body 104 in the prospective transistor area. Although a single gate dielectric 110 is employed in the exemplary IC 102, different oxide materials and/or oxides of different thicknesses can be separately formed at 162 for the prospective first and second transistors T1 and T2 of a composite transistor TC of the invention.

One or more gate electrode layers are formed at 162 over the gate dielectric. Any suitable materials can be used to form the gate electrodes within the scope of the invention, for example, conductive metals or semiconductor materials that can be doped to provide a conductive electrode for the subsequently patterned gate structures G1 and G2, or stacks or multi-layer combinations thereof. In FIG. 4D, a single layer of polysilicon 112 is deposited over the gate dielectric 110, where the polysilicon 112 can be of any suitable thickness and can be formed by any suitable deposition process. It is noted that although the first gate electrode 112a in the device 102 of FIG. 2B extends over the entirety of the corresponding first gate oxide 110a, alternative implementations are possible wherein a thicker field oxide, STI or other isolation structure (not shown) may be formed over part of the first channel region 128a in forming the DEMOS portion T1 of the composite transistor TC, wherein all such variant implementations having a first gate dielectric 110a formed at least partially over the first channel region 128a of the semiconductor body 104, and a conductive first gate electrode 112a formed at least partially over the first gate dielectric 110a are contemplated as falling within the scope of the invention. The gate dielectric and gate electrode layers are then patterned at 164 to form first and second gates G1 and G2. In FIG. 4E, a mask 222 is formed that covers portions of the deposited polysilicon 112 in prospective first and second gate regions of the IC 102, and a wet or dry etch process 224 (e.g., reactive ion etching, etc.) is performed to remove the exposed polysilicon, leaving the patterned gate structures G1 and G2.

At 166, one or more N+ pocket implant regions are formed, for example, by selective implantation of n-type dopants into portions of the semiconductor body 104. In FIG. 4F, a mask 232 is formed over the semiconductor body 104, exposing prospective pocket implant regions 122 (e.g., prospective source and shared source/drain regions), and an implantation process 230 is performed using the patterned gate structures G1 ands G2 for alignment of the resulting N+ pocket regions. The n-type pocket implant 230 may be an angled implant so as to locate some of the n-type dopants slightly under the edges of the first and second gate structures G1 and G2 as illustrated in FIG. 4F. As illustrated in FIG. 4F, the pocket implantation 230 essentially provides two N+ implanted regions in the n-well 106 on either side of the second gate 112b, including three corner regions 122a, 122b, and 122c that provide pockets in the finished composite transistor (e.g., as illustrated in FIG. 2B). A first pocket implant region 122a is created in a prospective first device channel region at a prospective shared source/drain end thereof in the n-well 106 to increase the n-type dopant concentration (N+), wherein the resulting pocket 122a will be situated along a portion of the channel side of the subsequently formed shared source/drain 114b (FIG. 2B above). In addition, second and third pocket implant regions 122b and 122c are provided at two lateral ends of a prospective second channel region 128b, wherein the second and third pocket implant regions 122b and 122c may, but need not, overlap under the second gate 112b. The three exemplary pocket implants 122 are formed concurrently through a single implantation 230 in the illustrated IC 102, although separate implantations may alternatively be employed, wherein the pocket implantations 122 may, but need not, be of similar or identical dimensions, concentrations, or dopant species within the scope of the invention.

At 168, one or more lightly-doped drain (LDD) or moderately-doped drain (MDD) implants are performed to provide p-type dopants to the composite transistor source region 114c and the shared source/drain 114b. As illustrated in FIG. 4G, with the mask 232 remaining over the IC 102, an implantation process 234 is performed to provide p-type dopants to the exposed source region 114c and the shared source/drain region 114b, thereby doping shallow portions thereof. Sidewall spacers are formed at 170, such as spacers 116 in FIG. 4H, along the lateral sidewalls of the patterned gate structures G1 and G2. Any suitable materials and/or processes may be employed in forming the sidewall spacers 116 at 170, for example, single or multi-layer structures of silicon nitride or other suitable materials, which are initially deposited using a conformal deposition process, and then etched back using a generally anisotropic etch process (not shown), leaving the spacers 116 of FIG. 4H.

With the spacers 116 in place, one or more source/drain implantations are performed at 172 to provide p-type dopants into the exposed regions between the patterned gate/sidewall spacer structures 116 and the isolation structures 108, thereby defining the first drain 114a, the shared source/drain 114b, and the source 114c. In FIG. 4I, a mask 242 is formed that exposes the prospective composite transistor region, and an implantation process 244 is performed, wherein the process 244 concurrently provides p-type dopants to the gates 112a, 112b, and select portions of the source 114a, the shared source/drain 114b, and the drain 114a, and wherein the exemplary source/drain implantation 244 at 172 is generally deeper than the LDD implant at 168. Thereafter, silicide processing is performed at 174 to create conductive metal silicide material 118 as shown in FIG. 2B, after which metalization and other back-end processing is performed at 176 to create a multi-level interconnection structure (not shown), before the exemplary method 150 ends at 178.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. An analog power integrated circuit, comprising:
a first transistor, comprising:
an extended drain of a first conductivity type formed in a semiconductor body;
a first channel region of a second conductivity type formed in the semiconductor body; and
a first gate comprising a first gate dielectric formed at least partially over the first channel region of the semiconductor body, and a conductive first gate electrode formed at least partially over the first gate dielectric;
a second transistor, comprising:
a source of the first conductivity type formed in the semiconductor body;
a second channel region of the second conductivity type formed in the semiconductor body; and
a second gate comprising a second gate dielectric formed at least partially over the second channel region of the semiconductor body, and a conductive second gate electrode formed at least partially over the second gate dielectric; and
a shared source/drain of the first conductivity type formed between the first and second channel regions in the semiconductor body, wherein the first channel region extends between the extended drain and the shared source/drain, and wherein the second channel region extends laterally between the source and the shared source/drain.

2. The integrated circuit of claim 1, wherein the extended drain comprises:
a drain region of the first conductivity type formed in the semiconductor body, the drain region being laterally spaced from the first channel region; and
a drain extension region of the first conductivity type formed in the semiconductor body, the drain extension region extending at least partially between the drain region and the first channel region, and extending at least partially under the first gate.

3. The integrated circuit of claim 2, wherein the first channel region has a first channel length, wherein the second channel region has a second channel length, and wherein the first channel length is greater than the second channel length.

4. The integrated circuit of claim 3, wherein the first conductivity type is p-type and the second conductivity type is n-type.

5. The integrated circuit of claim 2, further comprising at least one pocket implant region of the second conductivity type in the second channel region.

6. The integrated circuit of claim 2, further comprising:
a first pocket implant region of the second conductivity type located in the first channel region along a portion of the shared source/drain;
a second pocket implant region of the second conductivity type located in the second channel region along another portion of the shared source/drain; and
a third pocket implant region of the second conductivity type located in the second channel region along a portion of the source.

7. The integrated circuit of claim 6, wherein the first channel region has a first channel length, wherein the second channel region has a second channel length, and wherein the first channel length is greater than the second channel length.

8. The integrated circuit of claim 6, wherein the first conductivity type is p-type and the second conductivity type is n-type.

9. The integrated circuit of claim 1, further comprising:
a first pocket implant region of the second conductivity type located in the first channel region along a portion of the shared source/drain;
a second pocket implant region of the second conductivity type located in the second channel region along another portion of the shared source/drain; and
a third pocket implant region of the second conductivity type located in the second channel region along a portion of the source.

10. The integrated circuit of claim 9, wherein the first channel region has a first channel length, wherein the second channel region has a second channel length, and wherein the first channel length is greater than the second channel length.

11. The integrated circuit of claim 9, wherein the first conductivity type is p-type and the second conductivity type is n-type.

12. The integrated circuit of claim 1, wherein the first channel region has a first channel length, wherein the second channel region has a second channel length, and wherein the first channel length is greater than the second channel length.

13. The integrated circuit of claim 1, wherein the first conductivity type is p-type and the second conductivity type is n-type.

14. The integrated circuit of claim 1, wherein the first conductivity type is n-type and the second conductivity type is p-type.

15. A composite transistor, comprising:
an extended drain MOS transistor; and
a symmetrical MOS transistor;
wherein the extended drain MOS transistor and the symmetrical MOS transistor share a common source/drain.

16. The composite transistor of claim 15, wherein the extended drain MOS transistor comprises:
an extended drain of a first conductivity type formed in a semiconductor body;
a first channel region of a second conductivity type formed in the semiconductor body between the extended drain and the common source/drain; and
a first gate comprising a first gate dielectric formed at least partially over the first channel region; and a conductive first gate electrode formed at least partially over the first gate dielectric.

17. The composite transistor of claim 16, wherein the symmetrical MOS transistor comprises:
a source of the first conductivity type formed in the semiconductor body;
a second channel region of the second conductivity type formed in the semiconductor body between the source and the common source/drain; and
a second gate comprising a second gate dielectric formed at least partially over the second channel region, and a conductive second gate electrode formed at least partially over the second gate dielectric.

18. The composite transistor of claim 17, wherein the extended drain comprises a drain region of the first conductivity type laterally spaced from the first channel region in the semiconductor body; and a drain extension region of the first conductivity type extending at least partially between the drain region and the first channel region in the semiconductor body.

19. The composite transistor of claim 17, wherein the first channel region has a first channel length, wherein the second channel region has a second channel length, and wherein the first channel length is greater than the second channel length.

20. The composite transistor of claim 17, wherein the first conductivity type is p-type and the second conductivity type is n-type.

21. The composite transistor of claim 17, further comprising:
a first pocket implant region of the second conductivity type located in the first channel region along a portion of the common source/drain;
a second pocket implant region of the second conductivity type located in the second channel region along another portion of the common source/drain; and
a third pocket implant region of the second conductivity type located in the second channel region along a portion of the source.

22. The composite transistor of claim 17, wherein the first conductivity type is n-type and the second conductivity type is p-type.

23. The composite transistor of claim 15, wherein the extended drain MOS transistor comprises a first channel of a first length, wherein the symmetrical MOS transistor comprises a second channel of a second length, and wherein the first length is greater than the second length.

24. A method of fabricating an integrated circuit, the method comprising:
forming an extended drain of a first conductivity type in a semiconductor body;
forming a source of the first conductivity type in the semiconductor body;
forming a first channel of a second conductivity type along at least a portion of a side of the extended drain in the semiconductor body;
forming a first gate over at least a portion of the first channel;
forming a second channel of the second conductivity type along at least a portion of a side of the source;
forming a second gate over at least a portion of the second channel; and
forming a shared source/drain of the first conductivity type extending between the first and second channels.

25. The method of claim 24, further comprising:
forming a first pocket implant region of the second conductivity type in a portion of the first channel along a portion of the shared source/drain;
forming a second pocket implant region of the second conductivity type in a portion of the second channel along another portion of the shared source/drain; and
forming a third pocket implant region of the second conductivity type in the another portion of the second channel along a portion of the source.
